(19) United States
(12) Patent Application Publication
(10) Pub. No.: US 2008/0023221 A1
(43) Pub. Date: Jan. 31, 2008

(54) VIA STRUCTURE OF PRINTED CIRCUIT BOARD

(75) Inventors: SHOU-KUO HSU, Tu-Cheng (TW); YU-CHANG PAI, Tu-Cheng (TW); CHENG-HONG LIU, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/565,651

(22) Filed: Dec. 1, 2006

(30) Foreign Application Priority Data
Jul. 28, 2006 (CN) 200620200658.8

(51) Int. Cl. H05K 1/11; H01R 12/04

(52) U.S. Cl. 174/262

(57) ABSTRACT

An exemplary printed circuit board includes at least a pair of differential vias defined therein, each of the differential vias has an annular ring formed on the PCB, a conductive hole defined in the PCB, and a clearance hole defined in at least one inner layer of the PCB. Each of the clearance holes of the differential vias is oval shaped thus providing a greater area for the clearance holes and needed clearance between vias without creating a superposition zone.

### BACKGROUND OF THE INVENTION

1. Field of the Invention

The present invention relates to printed circuit boards, and particularly to the structure of differential vias of a printed circuit board.

2. Description of Related Art

As well known to those skilled in the art, a conventional printed circuit board (PCB) functions to connect various electronic components to each other on the PCB along a predetermined pattern, and is applied to various electronic goods such as home appliances including digital televisions and advanced telecommunication equipment. A conventional PCB comprises a copper plate on which a circuit pattern is formed, and at least an inner layer.

FIG. 3 is a schematic diagram of a portion of a conventional PCB 10 defining a pair of differential vias 11. Each of the vias 11 includes an upper cap (annular ring) 12, a conductive hole 14, and a clearance hole 16. The clearance hole 16 is circular shaped in an inner layer of the PCB 10, and a space 18 is left between the clearance holes 16 of the differential vias 11 for protecting stability of signals transmitted in the inner layer.

The capacitance of each of the differential vias 11 which depend on the area of the clearance holes 16 is one of the most important parameters for PCB designers, because the capacitances of the differential vias 11 may reduce the quality of a signal transmitted through the differential vias 11.

Referring to FIG. 4, another conventional PCB 20 defining a pair of differential vias 21 each having an annular ring 22, a conductive hole 24, and a circular shaped clearance hole 26 in an inner layer of the PCB 20 is shown. The clearance hole 26 is larger than the clearance hole 16 for reducing a capacitance of the vias 21.

However, the clearance holes 26 may define a superposition zone 28, and the existence of the superposition zone 28 may reduce the stability of signals transmitted in the inner layer of the PCB 20.

What is needed, therefore, is a printed circuit board which can solve the above problem.

### SUMMARY OF THE INVENTION

An exemplary printed circuit board includes at least a pair of differential vias defined therein, each of the differential vias has an annular ring formed on the PCB, a conductive hole defined in the PCB, and a clearance hole defined in each inner layer of the PCB. Each of the clearance holes of the differential vias is oval shaped in the inner layers thus providing needed clearance between vias without creating a superposition zone.

Other advantages and novel features will become more apparent from the following detailed description when taken in conjunction with the accompanying drawings, in which:

### BRIEF DESCRIPTION OF THE DRAWINGS

FIG. 1 is a schematic diagram of one embodiment of a printed circuit board with vias in accordance with the present invention;

FIG. 2 is a cross-sectional view taken along line II-II of FIG. 1;

FIG. 3 is a schematic diagram of a portion of a conventional printed circuit board with vias; and

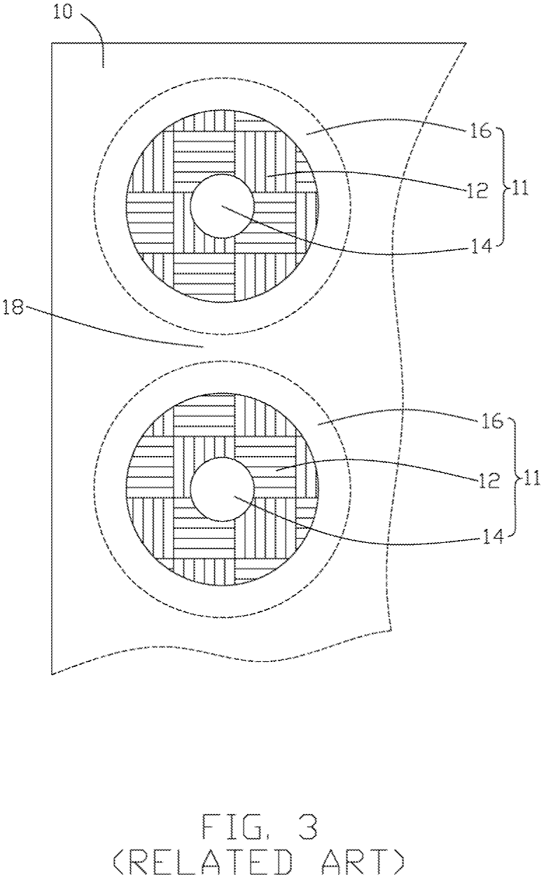

FIG. 4 is a schematic diagram of a portion of another conventional printed circuit board with vias.

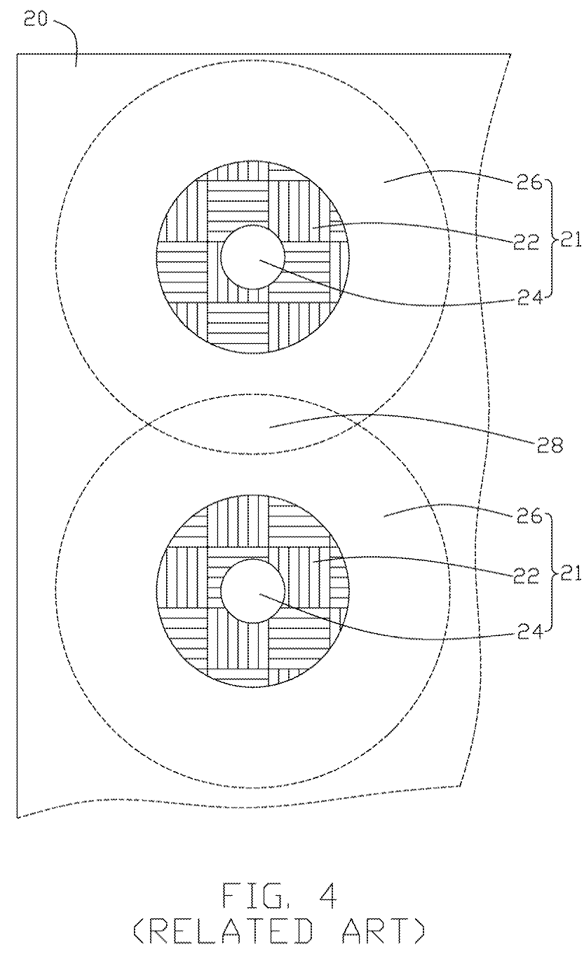

### DETAILED DESCRIPTION OF THE INVENTION

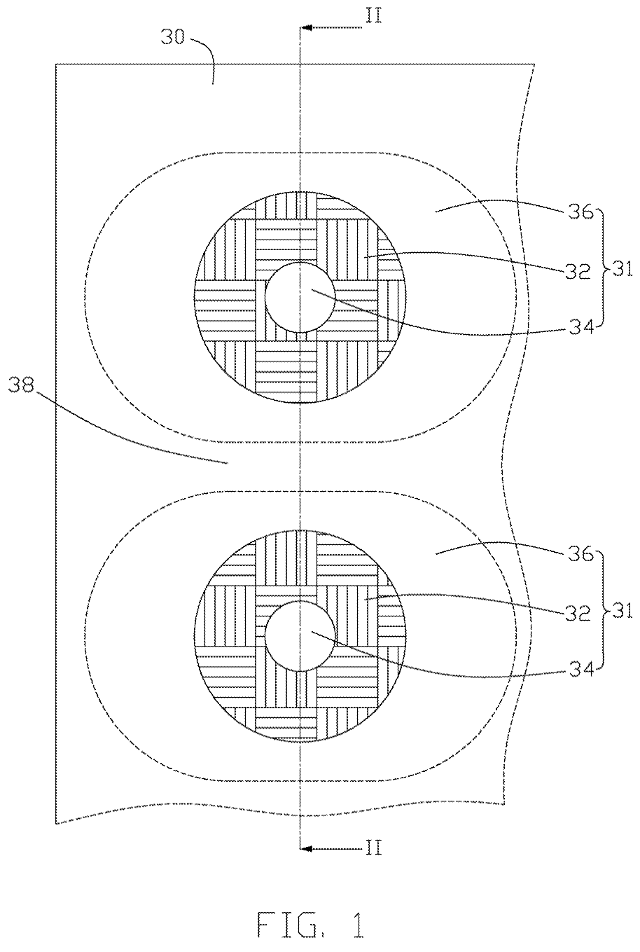

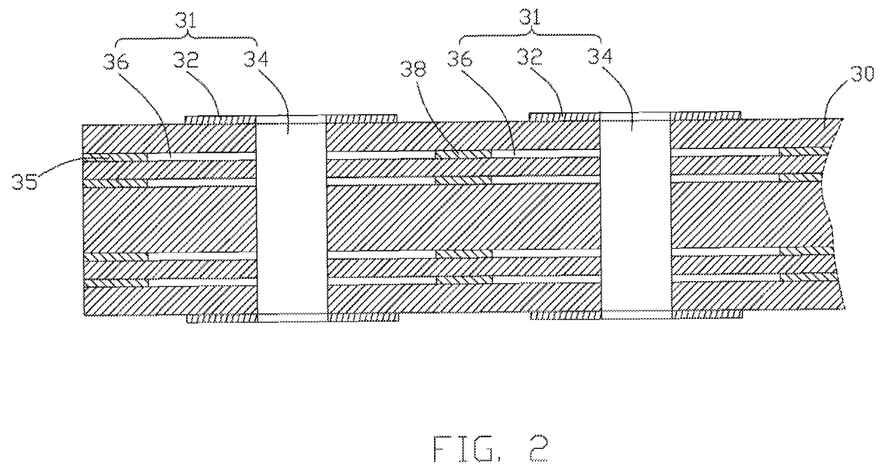

Referring to FIG. 1 and FIG. 2, a PCB 30 in accordance with a preferred embodiment of the present invention includes a pair of differential vias 31 and at least one inner layer 35. Each of the differential vias 31 includes an upper cap 32, a conductive hole 34, and a clearance hole 36.

The clearance hole 36 is oval shaped in the inner layer 35 of the PCB 30. The semi-minor axis of each clearance hole 36 is on a line connecting the centers of the differential vias 31. Therefore, a space 38 is left between the two clearance holes 36 in the inner layer 35 for protecting stability of signals transmitted in the inner layer 35.

Compared with the circular shaped clearance hole 16 of the conventional PCB 10, the oval shaped clearance holes 36 of the differential vias 31 have a greater area but still provide a space 38 therebetween without forming a superposition zone, thus protecting the stability of the signals transmitted in the inner layer 35 of the PCB 30.

It is believed that the present invention and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. A printed circuit board defining at least a pair of differential vias, each of the differential vias comprising:
an annular ring formed on an outer surface of the PCB;
a conductive hole defined in the PCB; and
a clearance hole defined in at least one inner layer of the PCB, wherein the clearance hole is oval shaped, and a space is left between the clearance holes of the at least a pair of differential vias.

2. A printed circuit board comprising:
at least one outer layer;
at least one inner layer; and
at least a pair of differential vias each comprising;
an annular ring formed on the at least one outer layer;
a conductive hole extending through the at least one outer layer and the at least one inner layer; and
a clearance hole defined in the at least one inner layer, wherein the clearance hole is oval shaped, and a space is left between the clearance holes of the at least a pair of differential vias.

3. The printed circuit board as claimed in claim 2, wherein the annular ring, the conductive hole and the clearance hole are coaxial.

4. The printed circuit board as claimed in claim 3, comprising two outer layers each of which has formed thereon at least two annular rings corresponding to the at least a pair of differential vias.
